(19) United States
(12) Patent Application Publication
(10) Pub. No.: US 2015/0017756 A1
(43) Pub. Date: Jan. 15, 2015

(54) APPARATUS AND METHOD FOR PRODUCING CIGS ABSORBER LAYER IN SOLAR CELLS

(71) Applicant: TSMC Solar Ltd., Taichung City (TW)

(72) Inventors: Shih-Wei CHEN, Kaohsiung City (TW); Li XU, Taichung City (TW)

(21) Appl. No.: 13/938,277

(22) Filed: Jul. 10, 2013

(51) Int. Cl. H01L 31/18

(52) U.S. Cl. CPC H01L 31/18
USPC 438/95

(57) ABSTRACT

A method of forming an absorber layer of a solar cell includes forming a plurality of precursor layers over a surface of a bottom electrode of a solar cell substrate. The step of forming includes depositing a first layer comprising selenium and copper and at least one of gallium or indium over at least a portion of the surface using a sputtering source or an evaporation source, the first layer having a first concentration of copper, depositing a second layer comprising selenium and at least one of the group consisting of copper, gallium or indium over at least the portion of the surface, the second layer having a second concentration of copper less than the first concentration of copper, and annealing the precursor layers to form an absorber layer.

### FIELD

The present disclosure relates generally to the field of photovoltaics, and more specifically to an apparatus and method for producing copper indium gallium diselenide (CIGS) absorber layers in solar cells.

### BACKGROUND

Copper indium gallium diselenide (CIGS) is a commonly used absorber layer in thin film solar cells. CIGS thin film solar cells have achieved excellent conversion efficiency (>20%) in laboratory environments. Most conventional CIGS deposition is done by one of two techniques: co-evaporation or selenization. Co-evaporation involves simultaneously evaporating copper, indium, gallium and selenium. The different melting points of the four elements makes controlling the formation of a stoichiometric compound on a large substrate very difficult. Additionally, it is difficult to achieve successful film adhesion when using co-evaporation. Selenization involves a two-step process. First, a copper, gallium, and indium precursor is sputtered on to a substrate. Second, selenization occurs by reacting the precursor with toxic H₂Se/H₂S at 500° Celsius or above.

### BRIEF DESCRIPTION OF THE DRAWINGS

Various aspects of the present disclosure will be or become apparent to one with skill in the art by reference to the following detailed description when considered in connection with the accompanying exemplary non-limiting embodiments.

FIG. 1 is a schematic diagram illustrating a top view of an example of a solar cell forming apparatus according to embodiments of the present disclosure.

FIGS. 2A-2E is a schematic diagram illustrating various precursor layer compound combinations used in forming an absorber layer according to some embodiments.

FIG. 3 is a schematic diagram illustrating a simplified top view of an example of a solar cell forming apparatus according to some embodiments.

FIG. 4 is a schematic diagram illustrating a top view of an example of another solar cell forming apparatus according to some embodiments.

FIG. 5 is a schematic diagram illustrating a precursor layer compound combination used in forming an absorber layer using the solar cell forming apparatus of FIG. 4 according to embodiments of the present disclosure.

FIG. 6 is a flow chart illustrating a method of forming a solar cell absorber layer on the substrate according to embodiments of the present disclosure.

FIG. 7 is a flow chart illustrating another method of forming a solar cell absorber layer on the substrate according to embodiments of the present disclosure.

FIG. 8 is a flow chart illustrating a method of forming a solar cell according to embodiments of the present disclosure.

### DETAILED DESCRIPTION OF THE EXAMPLES

With reference to the Figures, where like elements have been given like numerical designations to facilitate an understanding of the drawings, the various embodiments of a multi-gate semiconductor device and methods of forming the same are described. The figures are not drawn to scale.

The following description is provided as an enabling teaching of a representative set of examples. Many changes can be made to the embodiments described herein while still obtaining beneficial results. Some of the desired benefits discussed below can be obtained by selecting some of the features or steps discussed herein without utilizing other features or steps. Accordingly, many modifications and adaptations, as well as subsets of the features and steps described herein are possible and may even be desirable in certain circumstances. Thus, the following description is provided as illustrative and is not limiting.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. The term “adjacent” as used herein to describe the relationship between structures/components includes both direct contact between the respective structures/components referenced and the presence of other intervening structures/components between respective structures/components.

As used herein, use of a singular article such as “a,” “an” and “the” in conjunction with an object is not intended to exclude pluralities of that article's object unless the context clearly and unambiguously dictates otherwise.

Improved apparatus and processes for manufacturing thin film solar cells or absorber layers for thin film solar cells are provided. By combining evaporation and sputtering processes into an apparatus and/or method of manufacturing thin film solar cells, an improved mixing of absorber layer atoms may be obtained with an easily scalable volume production.

Techniques that promote or accelerate atom diffusion reduce manufacturing time, cost, and resources. Atom or atomic diffusion is a process whereby the random thermally-activated movement of atoms in a solid results in the net transport of atoms from a region of higher concentration to a region of lower concentration.

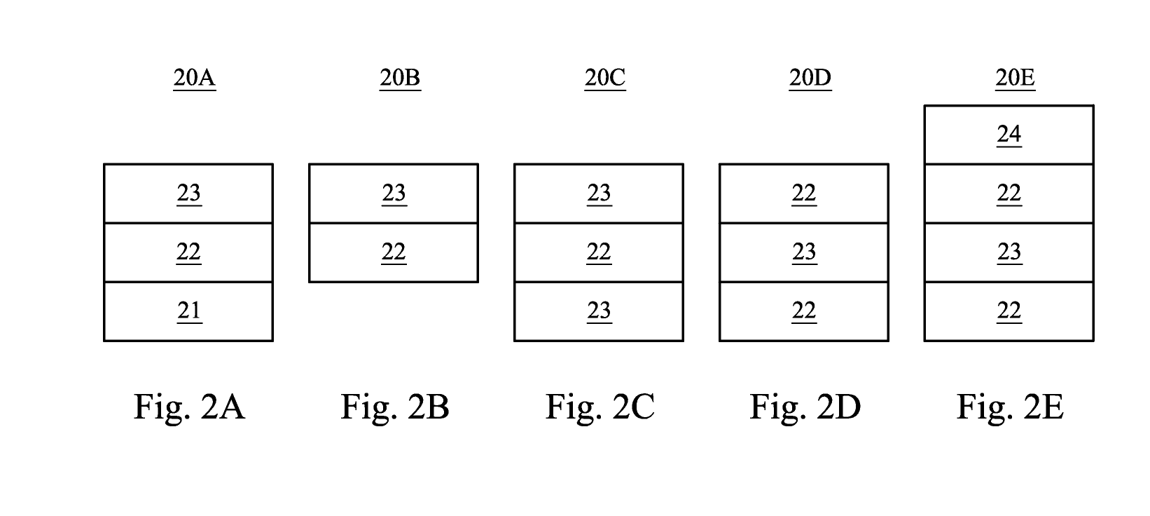

One technique to accelerate atom diffusion in the various embodiments herein include using a reaction pathway or reaction mechanism. In chemistry, a reaction mechanism is the step by step sequence of elementary reactions by which overall chemical change occurs. In this regard, a reaction pathway promoting the appearance of a copper-selenium (CuSe) phase helps grain growth and promotes atom diffusion. CuSe changes to a liquid phase at 800 Kelvin (or approximately 527 degrees Celsius) which helps grain growth and promotes atom diffusion. Another technique to accelerate atom diffusion involves reducing the distance between atoms and increasing the availability of selenium at various stages. If Cu and Se atoms mix well, approaching the CuSe phase occurs quickly. Furthermore, pre-mixing of elements minimizes or eliminates undesired diffusion process side effects such as gallium segregation towards the bottom of an absorber layer. In various embodiments, all precursor layers include selenium atoms that mix well with other atom types and each precursor layer includes different combinations of copper, indium or gallium. By “different combinations”, it should be understood that such combinations can include and are not limited to combinations that include selenium and copper or selenium and indium, or selenium and gallium or selenium and any combination or permutation of copper, indium or gallium (See FIG. 2).

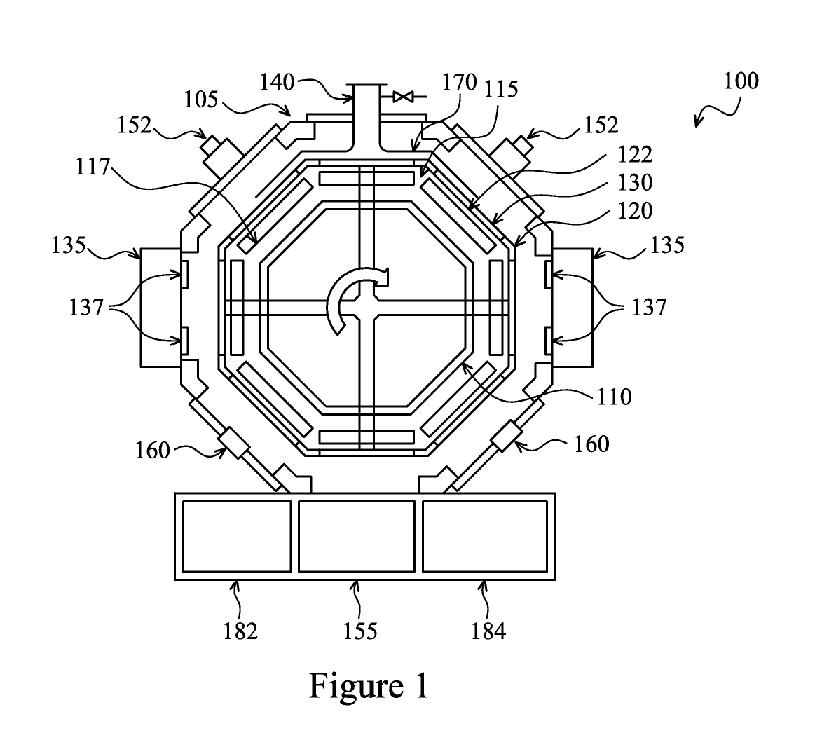

FIG. 1 is a schematic diagram illustrating a top view of an example of a solar cell forming apparatus 100 according to embodiments of the present disclosure. As shown, a solar cell forming apparatus 100 includes a housing 105 defining a vacuum chamber. In various embodiments, the housing 105 may be shaped as a polygon. For example, as shown in the illustrated embodiment, the housing 105 may be octagonally shaped. In various embodiments, the housing 105 has one or more removable doors built on one or more sides of the vacuum chamber. The housing 105 may be composed of stainless steel or other metals and alloys used for drum coater housings. For example, the housing 105 can define a single vacuum chamber having a height of approximately 2.4 m (2.3 m to 2.5 m) with a length and width of approximately 9.8 m (9.7 m to 9.9 m).

In some embodiments, the solar cell forming apparatus 100 includes a rotatable substrate apparatus 120 configured to hold a plurality of substrates 130 on a plurality of surfaces 122 where each of the plurality of surfaces 122 are disposed facing an interior surface of the vacuum chamber. In some embodiments, each one of the plurality of substrates 130 include a suitable material such as, for example, glass. In other embodiments, one or more of the plurality of substrates 130 include a flexible material. In some embodiments, the flexible material includes stainless steel. In other embodiments, the flexible material includes plastic. In various embodiments, the rotatable substrate apparatus 120 is shaped as a polygon. For example, in the illustrated embodiment, a plurality of substrates 130 are held on a plurality of surfaces 122 in a substantially octagonal shaped rotatable substrate apparatus 120. In other embodiments, for example, the substrate apparatus 120 may be rectangular shaped. Any suitable shape can be used for the rotatable substrate apparatus 120.

As shown in FIG. 1, the substrate apparatus 120 is rotatable about an axis in the vacuum chamber. FIG. 1 illustrates a clockwise direction of rotation for the rotatable substrate apparatus 120. In some embodiments, substrate apparatus 120 is configured to rotate in a counter-clockwise direction. In various embodiments, the rotatable substrate apparatus 120 is operatively coupled to a drive shaft, a motor, or other mechanism that actuates rotation from a surface of the vacuum chamber. In some embodiments, substrate apparatus 120 is rotated at a speed, for example, between approximately 5 and 100 RPM (e.g. 3 and 105 RPM). In various embodiments, a speed of rotation of the rotatable substrate apparatus 120 is selected to minimize excessive deposition of absorption components on the plurality of substrates 130. In some embodiments, the substrate apparatus rotates at a speed of approximately 80 RPM (e.g. 75-85 RPM). In some embodiments, the apparatus 100 includes a rotatable drum 110 disposed within the vacuum chamber and coupled to a first surface of the vacuum chamber. As illustrated in FIG. 1, the rotatable drum 110 can be disposed within the vacuum chamber. In the illustrated embodiment, the rotatable drum 110 is operatively coupled to the substrate apparatus 120. As shown, the rotatable drum 110 has a shape that is substantially conformal with the shape of the substrate apparatus 120. However, the rotatable drum can have any suitable shape.

In various embodiments, the apparatus 100 includes a first sputtering source 135 configured to deposit a plurality of absorber layer atoms of a first type over at least a portion of a surface of each one of the plurality of substrates 130. As shown in the illustrated embodiment, the first sputtering source 135 can be disposed within a vacuum chamber between the substrate apparatus 120 and the housing. The first sputtering source 135 can be coupled to a surface of the vacuum chamber. The first sputtering source 135 can be, for example, a magnetron, an ion beam source, a RF generator, or any suitable sputtering source configured to deposit a plurality of absorber layer atoms of a first type over at least a portion of a surface of each one of the plurality of substrates 130. In some embodiments, the first sputtering source 135 includes at least one of a plurality of sputtering targets 137. The first sputtering source 135 can utilize a sputtering gas. In some embodiments, sputtering is performed with an argon gas. Other possible sputtering gases include krypton, xenon, neon, and similarly inert gases.

As shown in FIG. 1, apparatus 100 can include a first sputtering source 135 disposed within the vacuum chamber and configured to deposit a plurality of absorber layer atoms of a first type over at least a portion of a surface of each one of the plurality of substrates 130 and a second sputtering source 135 disposed within the vacuum chamber and opposite the first sputtering source and configured to deposit a plurality of absorber layer atoms of a second type over at least a portion of a surface of each one of the plurality of substrates 130. In other embodiments, the first sputtering source 135 and the second sputtering source 135 are disposed adjacent to each other within the vacuum chamber. In some embodiments, the first and second sputtering sources 135 can each include at least one of a plurality of sputtering targets 137.

In various embodiments, a first sputtering source 135 is configured to deposit a plurality of absorber layer atoms of a first type (e.g. copper (Cu)) over at least a portion of a surface of each one of the plurality of substrates 130 and a second sputtering source 135 is configured to deposit absorber layer atoms of a second type (e.g. indium (In)) over at least a portion of a surface of each one of the plurality of substrates 130. In some embodiments, the first sputtering source 135 is configured to deposit a plurality of absorber layer atoms of a first type (e.g. copper (Cu)) and a third type (e.g. gallium (Ga)) over at least a portion of a surface of each one of the plurality of substrates 130. In some embodiments, a first sputtering source 135 includes one or more copper-gallium sputtering targets 137 and a second sputtering source 135 includes one or more indium sputtering targets 137. For example, a first sputtering source 135 can include two copper-gallium sputtering targets and a second sputtering source 135 can include two indium sputtering targets. In some embodiments, a copper-gallium sputtering target 137 includes a material of approximately 70 to 80% (e.g. 69.5 to 80.5%) copper and approximately 20 to 30% (e.g. 19.5 to 30.5%) gallium. In various embodiments, the solar cell forming apparatus 100 has a first copper-gallium sputtering target 137 at a first copper: gallium concentration and a second copper-gallium sputtering target 137 at a second copper: gallium concentration for grade composition sputtering. For example, a first copper-gallium sputtering target can include a material of 65% copper and 35% gallium to control monolayer deposition to a first gradient gallium concentration and a second copper-gallium sputtering target can include a material of 85% copper and 15% gallium to control monolayer deposition to a second gradient gallium concentration. The plurality of sputtering targets 137 can be any suitable size. For example, the plurality of sputtering targets 137 can be approximately 15 cm wide (e.g. 14-16 cm) and approximately 1.9 m tall (e.g. 1-8-2.0 m).

In some embodiments, a sputtering source 135 that is configured to deposit a plurality of absorber layer atoms of indium over at least a portion of the surface of each one of the plurality of substrates 130 can be doped with sodium (Na). For example, an indium sputtering target 137 of a sputtering source 135 can be doped with sodium (Na) elements. Doping an indium sputtering target 137 with sodium may minimize the need for depositing an alkali-silicate layer in the solar cell resulting in lower manufacturing costs for the solar cell as sodium is directly introduced to the absorber layer. In some embodiments, a sputtering source 135 is a sodium-doped copper source having between approximately two and ten percent sodium (e.g. 1.95 to 10.1 percent sodium). In various embodiments, an indium sputtering source 135 can be doped with other alkali elements such as, for example, potassium. In other embodiments, apparatus 100 can include multiple copper-gallium sputtering sources 135 and multiple sodium doped indium sputtering sources 135. For example, the solar cell forming apparatus can have a 65:35 copper-gallium sputtering source 135 and an 85:15 copper-gallium sputtering source 135 for grade composition sputtering.

In various embodiments, apparatus 100 includes an evaporation source 140 configured to deposit a plurality of absorber layer atoms of a fourth type over at least a portion of the surface of each one of the plurality of substrates 130. In various embodiments, the fourth type is non-toxic elemental selenium. The fourth type can include any suitable evaporation source material. In some embodiments, evaporation source 140 is configured to produce a vapor of an evaporation source material of the fourth type. In various embodiments, the vapor can condense upon the one or more substrates 130. For example, the evaporation source 140 can be an evaporation boat, crucible, filament coil, electron beam evaporation source, or any suitable evaporation source 140. In some embodiments, the evaporation source 140 is disposed in a first subchamber of the vacuum chamber 110. In various embodiments, the vapor of the fourth type evaporation source material can be ionized, for example using an ionization discharger, prior to condensation over the substrate to increase reactivity. In the illustrated embodiment, a first and second sputtering source 135 are disposed on opposing sides of the vacuum chamber and substantially equidistant from evaporation source 140 about the perimeter of the vacuum chamber.

In various embodiments, apparatus 100 includes a first isolation source such as an isolation pump 152 configured to isolate an evaporation source 140 from a first sputtering source 135. The isolation pump 152 can be a vacuum pump, for example. The first isolation source can be configured to prevent fourth type material from evaporation source 140 from contaminating the first sputtering source 135. In other embodiments, the apparatus 100 can include a plurality of isolation pumps 152. In various embodiments, the isolation source can include a combination of an isolation pump 152 and an isolation subchamber (not shown).

In some embodiments, the first isolation pump can include a vacuum pump 152 disposed within a first subchamber of the vacuum chamber to maintain the pressure in the first subchamber lower than the pressure in the vacuum chamber outside of the first subchamber. For example, the first isolation pump 152 can be disposed within a first subchamber of the vacuum chamber housing the evaporation source 140 to maintain the pressure in the first subchamber lower than the pressure in the vacuum chamber outside of the first subchamber and to isolate the evaporation source 140 from the first sputtering source. In various embodiments, the isolation source 152 can be an evacuation source 152 such as, for example, a vacuum pump 152 configured to evacuate atoms from the vacuum chamber to prevent contamination of a sputtering source 135.

For example, isolation source 152 can be a vacuum pump 152 disposed within a first subchamber of the vacuum chamber housing the evaporation source 140 and configured to evacuate evaporation source material atoms to prevent contamination of a sputtering source 135. In various embodiments, isolation source 152 can be a vacuum pump disposed along a perimeter surface of the vacuum chamber and configured to evacuate atoms (e.g. evaporation source material atoms) from the vacuum chamber to prevent contamination of sputtering source 135.

In embodiments including a plurality of sputtering sources 135 and/or a plurality of evaporation sources 140, apparatus 100 can include a plurality of isolation sources to isolate each of the evaporation sources from each of the sputtering sources 135. For example, in embodiments having first and second sputtering sources 135 disposed on opposing sides of a vacuum chamber and an evaporation source 140 disposed there between on a perimeter surface of the vacuum chamber, apparatus 100 can include a first isolation pump 152 disposed between the first sputtering source 135 and evaporation source 140 and a second isolation pump 152 disposed between the second sputtering source 135 and evaporation source 140. In the illustrated embodiment, apparatus 100 includes an isolation pump 152 disposed between evaporation source 140 and one of the two sputtering sources 135.

The solar cell forming apparatus 100 can include one or more heaters 117 to heat the plurality of substrates 130 disposed on a plurality of surfaces 122 of the rotatable substrate apparatus 120. In the illustrated embodiment, a plurality of heaters are disposed in a heater apparatus 115 to heat the plurality of substrates. As shown in FIG. 1, heater apparatus 115 can have a shape that is substantially conformal with the shape of the substrate apparatus. In the illustrated embodiment, the plurality of heaters 117 are shown positioned in a substantially octagonal shape arrangement within a heating apparatus 115. However, the heater apparatus 115 can have any suitable shape. In various embodiments, the heater apparatus 115 is disposed to maintain a substantially uniform distance about the perimeter of the substrate apparatus 120. In the illustrated embodiment, heater apparatus 115 is disposed about an interior surface of the rotatable substrate apparatus 120. In some embodiments, the heater apparatus 115 can be disposed about an interior surface of a rotatable drum 110. A power source of the heater apparatus 115 can extend through a surface of the rotatable drum 110. In various embodiments, the substrate apparatus 120 is rotatable around the heater apparatus 115. In some embodiments, the heater apparatus 115 is disposed about an exterior surface of a rotatable drum 110. In some embodiments, the heater apparatus 115 can be coupled to a surface of the vacuum chamber. The heater apparatus 115 can be rotatable. In other embodiments, the heater apparatus 115 is configured to not rotate. The one or more heaters 117 can include, but are not limited to, infrared heaters, halogen bulb heaters, resistive heaters, or any suitable heater for heating a substrate 130 during a deposition process. In some embodiments, the heater apparatus 115 can heat a substrate to a temperature between approximately 300 and 550 degrees Celsius (e.g. 295 and 555 degrees Celsius).

As shown in FIG. 1, apparatus 100 can include an isolation baffle 170 disposed about the evaporation source 140. Isolation baffle 170 can be configured to direct a vapor of an evaporation source material to a particular portion of a surface of the plurality of substrates 130. Isolation baffle 170 can be configured to direct a vapor of an evaporation source material away from a sputtering source 135. Apparatus 100 can optionally include an isolation baffle 170 in addition to one or more isolation sources to minimize evaporation source material 122 contamination of one or more sputtering sources 135. The isolation baffle 170 can be composed of a material such as, for example, stainless steel or other similar metals and metal alloys. In some embodiments, the isolation baffle 170 is disposable. In other embodiments, the isolation baffle 170 is cleanable. In yet other embodiments, no isolation baffle is used.

In some embodiments, apparatus 100 can include one or more in-situ monitoring devices 160 to monitor process parameters such as temperature, chamber pressure, film thickness, or any suitable process parameter. In various embodiments, apparatus 100, can include a load lock chamber 182 and/or an unload lock chamber 184. In embodiments of the present disclosure, apparatus 100 can include a buffer subchamber 155 (e.g. a buffer layer deposition subchamber) configured in-situ in apparatus 100 with a vacuum break. In some embodiments, a buffer layer deposition subchamber 155 configured in-situ in apparatus 100 with a vacuum break includes a sputtering source (not shown) including one or more sputtering targets (not shown). In various embodiments, apparatus 100 includes a sputtering source (not shown) disposed in a subchamber of the vacuum chamber and configured to deposit a buffer layer over a surface of each one of the plurality of substrates 130 in substrate apparatus 130. In various embodiments, apparatus 100 includes an isolation source to isolate the buffer layer sputtering source from an evaporation source and/or an absorber monolayer sputtering source. The buffer layer material can include, for example, non-toxic ZnS—O or CdS.

The embodiments herein are not limited to the apparatus 100 described above, but can include any apparatus with a combination of depositing devices such as evaporation sources and sputtering sources that provides a combination of selenium, copper, indium, gallium where all precursor layers have selenium atoms and where each precursor layer comprise different combinations of copper, indium, or gallium. The embodiments herein generally involve sequentially depositing precursor layers by an interlacing method which can be done at room temperature or low temperatures. Subsequently, the stacking layers are annealed at higher temperatures to make a chalcopyrite phase formation.

FIGS. 2A-2E illustrate a variety of layer combinations or stacks 20A-20B having the desired characteristics described above. Each of these layers can be sputtered, evaporated or otherwise deposited on the substrate to form the precursor. In the various layer combinations of FIGS. 2A-2E,
layer 21 includes In—Se or In—Ga—Se or Ga—Se,
layer 22 includes Cu—In—Ga—Se or Cu—Ga—Se or Cu—Se or Cu—In—Se,
layer 23 includes Cu—In—Ga—Se or Cu—Ga—Se or In—Se or Ga—Se or In—Ga—Se, and
layer 24 includes just Se which is an optional layer.

Layer 22 is known as a copper rich layer and layer 23 is known as a copper poor layer as they relate to a parameter referred to as the copper gallium indium or CGI ratio. The CGI ratio is defined as the following ratio of Cu mole/(Ga mole+In mole). When the CGI≧1, the layer is considered Cu rich, which will benefit CuSe phase appearance. When the CGI<0.7, the layer is considered Cu poor. Typically, a good CIGS absorber possess a CGI ratio of around 0.85-0.95. Thus, combinations of copper rich and copper poor layers are used to obtain a desirable final CGI ratio for the absorber layer.

Accordingly, the variations of layers shown in FIGS. 2A-2E include at least one copper rich layer 22 and one copper poor layer 23. In FIG. 2A, stack 20A includes a bottom layer 21 having In—Se or In—Ga—Se or Ga—Se is combined with a copper rich layer 22 and a copper poor layer 23. In FIG. 2B, stack 20B just has a copper rich layer 22 and a copper poor layer 23. The stack 20C of FIG. 2C includes a bottom layer having a copper poor layer 22 followed by a copper rich layer 23 and then another copper poor layer 22. The stack 20D of FIG. 2D includes a copper rich layer 22 followed by a copper poor layer 23 and then another copper rich layer 22. The stack 20E of FIG. 2E includes a copper rich layer 22 followed by a copper poor layer 23, another copper rich layer 22, and then an optional selenium layer 24

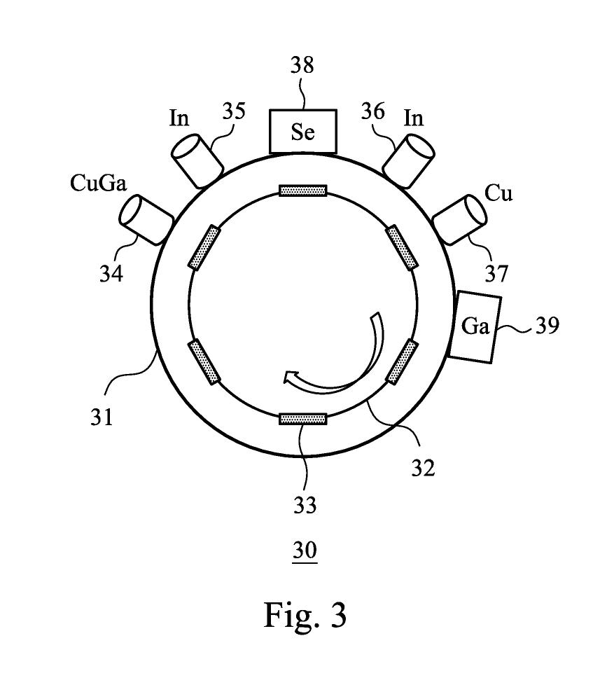

FIG. 3 illustrates a simplified top view of an example of a solar cell forming apparatus 30 that includes a housing 31 defining a vacuum chamber. In various embodiments, the housing 31 may be shaped as a circular drum or a polygon as discussed above in the description of FIG. 1. The housing 31 can be composed of stainless steel or other metals and alloys used for drum coater housings. The apparatus 30 further includes a rotatable substrate apparatus 32 configured to hold a plurality of substrates 33 on a plurality of surfaces or on portions of the surface of the rotatable substrate apparatus. In some embodiments, each one of the plurality of substrates 33 include a suitable material such as, for example, glass. In other embodiments, one or more of the plurality of substrates 3 include a flexible material, such as foil. In some embodiments, the flexible material includes stainless steel. In other embodiments, the flexible material includes plastic such as polyimide. Any suitable shape can be used for the rotatable substrate apparatus 32 (e.g., circular, hexagonal, octagonal, or the like). The apparatus 30 can be a hybrid system that includes sputtering and/or evaporation sources.

In various embodiments, the apparatus 30 includes two or more sputtering sources 34-37 configured to deposit a plurality of absorber layer atoms over at least a portion of a surface of each one of the plurality of substrates 33. A first sputtering source 34 can be disposed as part of a vacuum chamber between the substrate apparatus 32 and the housing 31. The first sputtering source 34 as the other sputtering sources (35-37) can be coupled to a surface of the vacuum chamber. The first sputtering source 34 can be, for example, a magnetron, an ion beam source, a RF generator, or any suitable sputtering source configured to deposit a plurality of absorber layer atoms of a first type over at least a portion of a surface of each one of the plurality of substrates 33. The first sputtering source 34 can utilize a sputtering gas. In some embodiments, sputtering is performed with an argon gas. Other possible sputtering gases include krypton, xenon, neon, and similarly inert gases.

In various embodiments, the first sputtering source 34 is configured to deposit a plurality of absorber layer atoms of a first type such as copper-gallium. In various embodiments, a second sputtering source 35 and a third sputtering source 36 are configured to deposit a plurality of absorber layer atoms of a second type (e.g. indium (in)) over at least a portion of a surface of each one of the plurality of substrates 33 and a fourth sputtering source 37 is configured to deposit absorber layer atoms of a third type type (e.g. copper (cu)) over at least a portion of a surface of each one of the plurality of substrates 33.

In various embodiments, apparatus 30 includes one or more evaporation sources 38 and 39 configured to deposit a plurality of absorber layer atoms over at least a portion of the surface of each one of the plurality of substrates 33. In various embodiments, the evaporation source 38 can be a non-toxic elemental selenium. In some embodiments, the evaporation source 39 can provide gallium. In some embodiments, evaporation source 38 or 39 is configured to produce a vapor of an evaporation source material that can condense upon the one or more substrates 33. For example, the evaporation source 38 or 39 can be an evaporation boat, crucible, filament coil, electron beam evaporation source, or any suitable evaporation source. In various embodiments, the vapor of the evaporation source material can be ionized, for example using an ionization discharger, prior to condensation over the substrate to increase reactivity. The combinations of sputtering sources and evaporation sources and the deposit materials can generally match the combination of layers described with respect to FIGS. 2A-2E.

The apparatus 30 performs steps in precursor deposition. Subsequent to precursor deposition, the substrates continue to an annealing process that can include any thermal process. Such thermal process can include furnace annealing or rapid thermal annealing or a combination of furnace annealing and rapid thermal annealing. The atmosphere for annealing includes a vacuum with N₂, H₂, Ar, H₂Se, H₂S, Se, S, or any recombination thereof

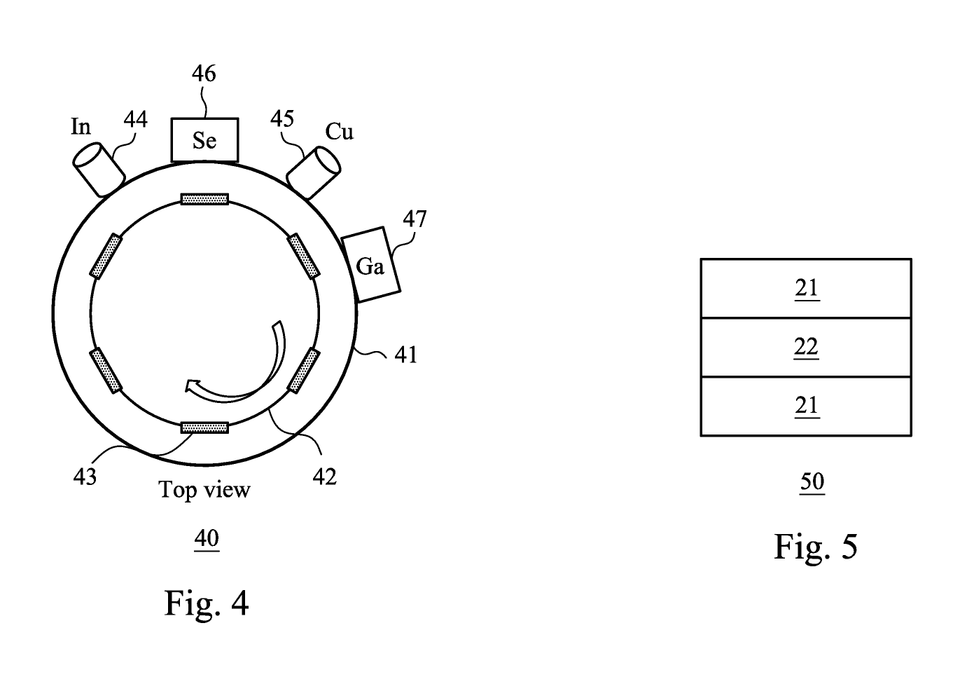

FIG. 4 illustrates another a simplified top view of an example of a solar cell forming apparatus 40 similar to the apparatus 30 of FIG. 3 that includes a housing 41 defining a vacuum chamber. The apparatus 40 further includes a rotatable substrate apparatus 42 configured to hold a plurality of substrates 43 on a plurality of surfaces or on portions of the surface of the rotatable substrate apparatus.

In various embodiments, the apparatus 40 includes two or more sputtering sources 44-45 configured to deposit a plurality of absorber layer atoms over at least a portion of a surface of each one of the plurality of substrates 43. A first sputtering source 44 can be disposed as part of a vacuum chamber between the substrate apparatus 42 and the housing 41. In various embodiments, the first sputtering source 44 is configured to deposit a plurality of absorber layer atoms of a first type such as indium. In various embodiments, a second sputtering source 45 is configured to deposit a plurality of absorber layer atoms of a second type (e.g. copper (cu)) over at least a portion of a surface of each one of the plurality of substrates 43.

In various embodiments, apparatus 40 includes one or more evaporation sources 46 and 47 configured to deposit a plurality of absorber layer atoms over at least a portion of the surface of each one of the plurality of substrates 43. In various embodiments, the evaporation source 46 can be a non-toxic elemental selenium. In some embodiments, the evaporation source 47 can provide gallium. In some embodiments, evaporation source 46 or 47 is configured to produce a vapor of an evaporation source material that can condense upon the one or more substrates 43. For example, the evaporation source 46 or 47 can be an evaporation boat, crucible, filament coil, electron beam evaporation source, or any suitable evaporation source. In various embodiments, the vapor of the evaporation source material can be ionized, for example using an ionization discharger, prior to condensation over the substrate to increase reactivity. The combinations of sputtering sources and evaporation sources and the deposit materials can generally match the combination of layers described with respect to the layers shown in FIG. 5.

Stack 50 of FIG. 5 includes a copper rich layer 22 stacked on a layer 21 having In—Se or In—Ga—Se or Ga—Se followed by a second layer 21. Note that this arrangement does not include both a copper rich layer and a copper poor layer. In one embodiment, the layer 21 can include In—Ga—Se in a bottom layer 21, Cu—Se in layer 22, and In—Ga—Se in a top layer 21.

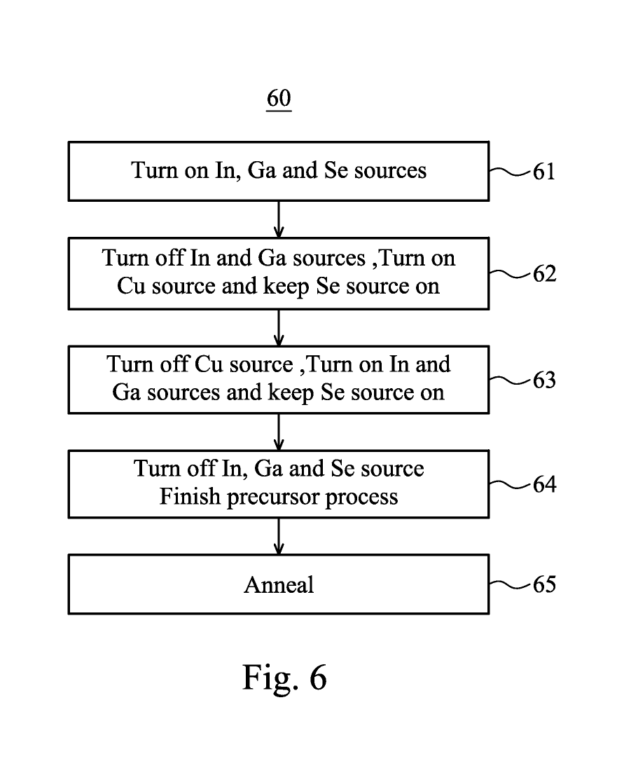

The flow chart of FIG. 6 illustrates a method 60 of processing a an absorber layer corresponding to the precursor layers 21, 22, and 22 of stack 50 of FIG. 5 when the layer 21 includes In—Ga—Se in a bottom layer 21, Cu—Se in layer 22, and In—Ga—Se in a top layer 21.

At step 61 and with further reference to FIG. 4, the indium source 44, gallium source 47 and selenium source 46 are turned on. Step 61 corresponds to the provision of bottom layer 21 of FIG. 5.

At step 62, the indium and gallium sources 44 and 47 are turned off and the copper source 45 is turned on while the selenium source 46 remains on. Step 62 corresponds to the provision of the copper rich layer 22.

At step 63, the copper source 45 is turned off and the indium source 44 and gallium source 47 are turned back on while the selenium source 46 continues to remain on. Step 63 corresponds to the top layer 21.

At step 64, the precursor deposition process is completed by turning off the indium source 44, the gallium source 47, and the selenium source 46 and then the precursor process is finished.

At step 65, the precursor process is followed by annealing.

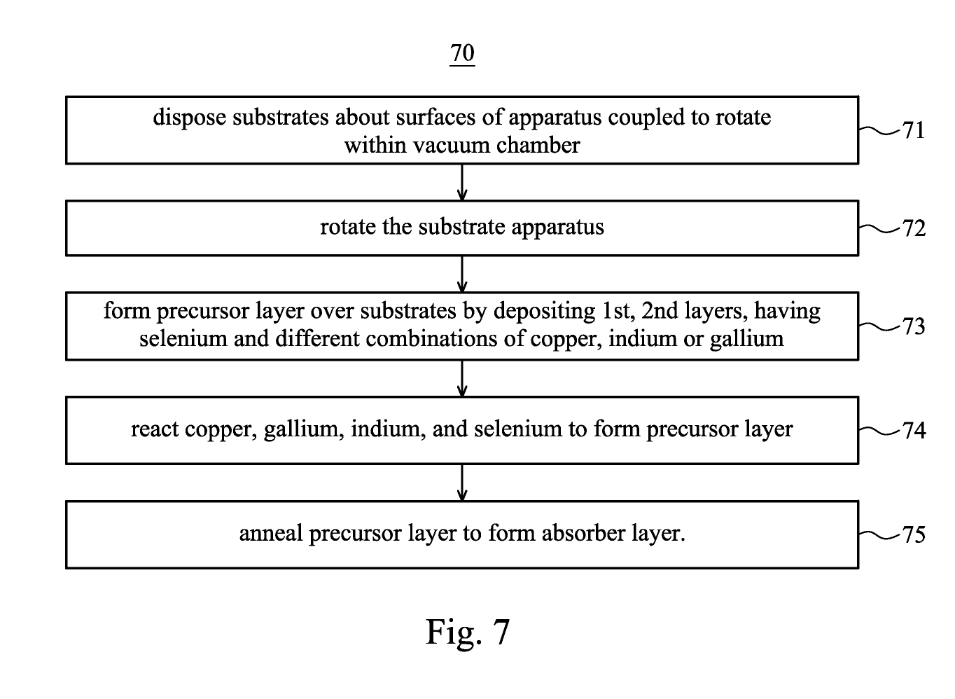

Referring to FIG. 7, a method 70 of forming a solar cell includes the step 71 of disposing a plurality of substrates about a plurality of surfaces of a substrate apparatus that is operatively coupled to rotate within a vacuum chamber. The substrate apparatus can carry the plurality of substrates through a precursor layer deposition process.

In some embodiments, at step 72, the method continues by rotating the substrate apparatus.

At step 73, the method 70 forms a precursor layer over a surface of each one of the plurality of substrates by depositing at least a first layer and a second layer, the first and second layers each having at least a plurality of selenium atoms and each layer comprising different combinations of copper, indium or gallium. The various combinations of layers include, but are not limited to the various layer combinations illustrated in FIGS. 2A-2E and in FIG. 5.

At step 74, the precursor layer is formed by reacting the plurality of copper, gallium, indium, and selenium atoms. In accordance with the embodiments, selenium atoms exist in each of the layers deposited and each layer includes some combination of copper, gallium, or indium.

At step 75, the absorber layer is formed by annealing the precursor layers subsequent to reacting the atoms in step 74.

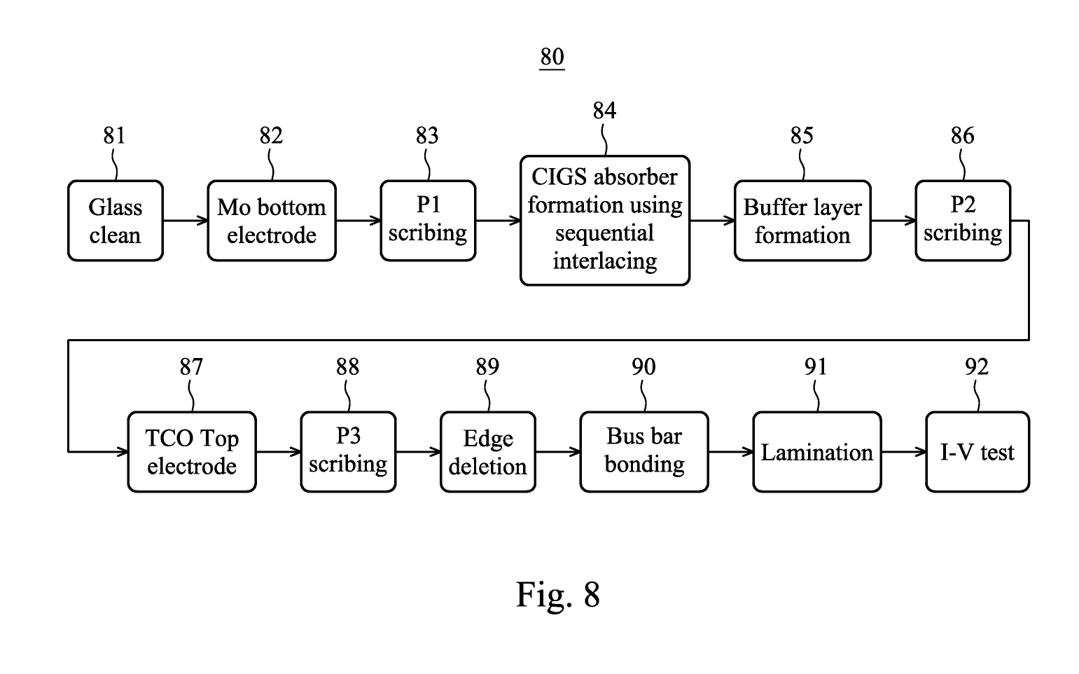

Referring to FIG. 8, an example of a flow chart of making a solar cell is shown in further detail.

At step 81 a glass substrate is provided and cleaned.

At step 82, a back contact layer is formed on the substrate by sputtering Mo or molybdenum.

At step 83, scribing of the P1 line can be done.

At step 84, an absorber layer is formed on the back contact layer using sequential interlacing as described above. Sequential interlacing interlaces layers of combinations of Cu, In, Ga, and Se in a number of combinations or permutations. As noted above, the combinations include selenium in each layer.

In some embodiments, step 84 can provide for the co-evaporation of Cu, In, Ga, and Se. In other embodiments, step 84, can provide for the sputtering of Cu, In, CuGa, and CuInGa. In yet other embodiments, step 84 can provide for the sputtering of Cu, In, CuGa, and CuInGa+ the evaporation of Se.

At step 85, the method continues by chemical bath deposition of cadmium sulfide or zinc sulfide to form a buffer layer.

After step 85, P2 scribing at step 86 can be done.

At step 87, the TCO is deposited.

At step 88, P3 scribing is performed.

At step 89, appropriate edge deletion is performed.

At step 90, the bus bar is bonded to the substrate.

At step 91, the transfer or delamination step occurs where the separation of an extracted portion of a solar cell assembly portion is separated and then adhered to another substrate.

At step 92, the solar cell can be tested using an I-V test.

Adjusting a power source of a sputtering source (e.g. sputtering sources 34-37 of FIG. 3) can control a sputtering rate and a concentration of the sputtered copper, copper-gallium, and/or indium atoms deposited over the substrate 33. Similarly, adjusting a power source of an evaporation source 38 or 39 can control an evaporation rate and a concentration of the evaporated selenium atoms or gallium atoms deposited over the substrate 33. The speed and/or direction of rotation of the substrate apparatus 32 also can affect the rate and amount of sputtered copper, copper-gallium, and/or indium atoms and the amount of evaporated selenium or gallium atoms deposited over the substrate 33. As described above, selecting the copper-gallium concentration in one or more copper-gallium sputtering targets of one or more sputtering sources (e.g. 34-37) or evaporation source (39) can control concentration of the sputtered copper and gallium atoms to a desired gradient concentration. In various embodiments, one or more of the power source of each sputtering source and each evaporation source, the sputtering rate of each sputtering source, the evaporation rate of each evaporation source is controlled to form a predetermined composition of a precursor layers. In various embodiments, the formed precursor layer(s) includes a composition of 20 to 24% copper, 4 to 14% gallium, 10 to 24% indium and 49 to 53% selenium. In some embodiments, the composition is 23% copper, 9% gallium, 17% indium, 51% selenium. Other varying concentrations are suitable as long as the resulting CGI ratio levels remain in a range about 0.85 to about 0.95 and each layer includes selenium.

In various embodiments, reaction using the precursory layers herein results in better uniformity and a more consistent and desired bandgap in the absorber layer. The sequential interlacing method of forming the precursor layers described herein results in a more accurate and improved process to achieve a desired precursory layer composition. In some embodiments, ionizing a plurality of the second absorption components such as, for example, selenium, can increase the reaction rate.

Throughout the description and drawings, examples are given with reference to specific configurations. It will be appreciated by those of ordinary skill in the art that the present disclosure can be embodied in other specific forms. Those of ordinary skill in the art would be able to practice such other embodiments without undue experimentation. The scope of the present disclosure, for the purpose of the present patent document, is not limited merely to the specific example embodiments or alternatives of the foregoing description.

As shown by the various configurations and embodiments illustrated in FIGS. 1-8 various improved CIGS films have been described.

According to some embodiments, a method of an absorber layer of a solar cell includes forming a plurality of precursor layers over a surface of a bottom electrode of a solar cell substrate. The step of forming includes depositing a first layer comprising selenium and copper and at least one of gallium or indium over at least a portion of the surface using a sputtering source or an evaporation source, the first layer having a first concentration of copper, depositing a second layer comprising selenium and at least one of the group consisting of copper, gallium or indium over at least the portion of the surface, the second layer having a second concentration of copper less than the first concentration of copper, and annealing the precursor layers to form an absorber layer. In one embodiment, the method further includes depositing a buffer layer over the absorber layer using another sputtering source.

In some embodiments, the absorber layer has a copper gallium indium ratio in a range about 0.85 to about 0.95. In another embodiment, the second layer includes at least one of the combinations of copper, indium, gallium and selenium or copper, gallium and selenium or indium and selenium, or indium, gallium and selenium. In one embodiment, the method further includes depositing a third layer before depositing the first layer, and before depositing the second layer, the third layer comprising selenium and at least one of the group consisting of indium or gallium. In one embodiment, the method further includes depositing a third layer before the first layer and before depositing the second layer, the third layer including at least one of the combinations of copper, indium, gallium and selenium or copper, gallium and selenium or indium and selenium, or indium, gallium and selenium.

In some embodiments, the method includes depositing a third layer after the first layer or the second layer, the third layer comprising selenium and copper and at least one of gallium or indium. In other embodiments, the method includes depositing a layer of selenium over the second layer. In some embodiments, the steps of depositing the first layer and the second layer include sputtering at least two of copper-gallium, indium or copper, and evaporating gallium and selenium. In one embodiment, the steps of depositing the first layer and the second layer include sputtering indium and copper and evaporating gallium and selenium. In one embodiment, the steps of depositing include, in the following order, providing material from an indium source, a gallium source, and a selenium source, providing material from a copper source, and providing material from the indium source and gallium source.

In some embodiments, the first layer has a copper gallium indium ratio of at least 1.0. In one embodiment, the second layer has a copper gallium indium ratio below 0.7. In another embodiment, the first layer has a copper gallium indium ratio of at least one (1) and the second layer has a copper gallium indium ratio below 0.7, so that the absorber layer has a copper gallium indium ratio in a range about 0.85 to about 0.95.

In some embodiments, a method of forming a precursor layer stack on a substrate of a solar cell for forming an absorber layer includes depositing a first layer including selenium and copper and at least one of gallium or indium over at least a portion of a surface of a bottom electrode of a solar cell substrate, the first layer having a first concentration of copper, and depositing a second layer comprising selenium and at least one of the group consisting of copper, gallium or indium over at least the portion of the surface, the second layer having a second concentration of copper less than the first concentration of copper.

In some embodiments, a method of forming an absorber layer of a solar cell includes forming a plurality of precursor layers over a surface of a bottom electrode of a solar cell substrate. The step of forming includes depositing a first layer including selenium and at least one of gallium or indium over at least a portion of the surface using a sputtering source or an evaporation source, depositing a second layer comprising selenium and copper and at least one of the group consisting of gallium or indium over at least the portion of the surface, and depositing a third layer comprising selenium and at least one of the group consisting of gallium or indium over at least the portion of the surface. The method further includes annealing the precursor layers to form an absorber layer.

In some embodiments the first layer includes selenium, gallium, and indium, the second layer includes copper and selenium, and the third layer includes selenium, gallium, and indium. In one embodiment, the steps of depositing the first and third layers include sputtering indium and evaporating gallium and selenium. In another embodiment, the step of deposition includes sputtering copper and evaporating selenium. In some embodiments, the absorber layer has a copper gallium indium ratio in a range about 0.85 to about 0.95.

Embodiments described are illustrative only and that the scope of the subject matter is to be accorded a full range of equivalents, many variations and modifications naturally occurring to those of skill in the art from a perusal hereof.

Furthermore, the above examples are illustrative only and are not intended to limit the scope of the disclosure as defined by the appended claims. Various modifications and variations can be made in the methods of the present subject matter without departing from the spirit and scope of the disclosure. Thus, it is intended that the claims cover the variations and modifications that can be made by those of ordinary skill in the art.

1. A method of forming an absorber layer of a solar cell, comprising:
forming a plurality of precursor layers over a surface of a bottom electrode of a solar cell substrate, the step of forming comprising:
depositing a first layer comprising selenium and copper over at least a portion of the surface using a sputtering source or an evaporation source, the first layer having a first concentration of copper;
depositing a second layer comprising selenium and at least two of the group consisting of copper, gallium or indium over at least the portion of the surface, the second layer having a second concentration of copper less than the first concentration of copper; and
annealing the precursor layers to form an absorber layer.

2. The method of claim 1, further comprising:
depositing a buffer layer over the absorber layer using another sputtering source.

3. The method of claim 1, wherein the absorber layer has a copper gallium indium ratio, calculated as copper mole/(gallium mole+indium mole), in a range about 0.85 to about 0.95.

4. The method of claim 3, wherein the second layer comprises at least one of the combinations of:
copper, indium, gallium and selenium or
copper, gallium and selenium or
indium, gallium and selenium.

5. (canceled)

6. (canceled)

7. The method of claim 4, further comprising depositing a third layer after the first layer or the second layer, the third layer comprising selenium and copper and at least one of gallium or indium.

8. The method of claim 7, further comprising depositing a layer of selenium over the second layer.

9. The method of claim 1, wherein the steps of depositing the first layer and the second layer comprise sputtering at least two of copper-gallium, indium or copper, and evaporating gallium and selenium.

10. (canceled)

11. The method of claim 1, wherein the steps of depositing are performed by:
providing a solar cell forming apparatus comprising a housing defining a vacuum chamber, a rotatable substrate apparatus within the housing for holding a substrate, and a copper source, an indium source, a gallium source, and a selenium source disposed within the vacuum chamber between the rotatable substrate apparatus and housing;
positioning the substrate on the rotatable substrate apparatus; and
rotating the rotatable substrate apparatus while providing material from a first combination of the sources, including the selenium source and the copper source then providing material from a second combination of the sources, including at least two of the group consisting of the copper source, the indium source and gallium source to deposit the second layer.

12. The method of claim 3, wherein the first layer has a copper gallium indium ratio of at least 1.0.

13. The method of claim 4, wherein the second layer has a copper gallium indium ratio below 0.7.

14. (canceled)

15. (canceled)

16. A method of forming an absorber layer of a solar cell, comprising:
forming a plurality of precursor layers over a surface of a bottom electrode of a solar cell substrate, the step of forming comprising:
depositing a first layer comprising selenium and at least one of gallium or indium over at least a portion of the surface using a sputtering source or an evaporation source;
depositing a second layer comprising selenium and copper over at least the portion of the surface, the second layer having a second concentration of copper;
depositing a third layer comprising selenium and at least two of the group consisting of copper, gallium or indium over at least the portion of the surface, the third layer having a third concentration of copper less than the second concentration of copper; and
annealing the precursor layers to form an absorber layer.

17. The method of claim 16, wherein the first layer comprises selenium, gallium, and indium, the second layer comprises copper and selenium, and the third layer comprises selenium, gallium, and indium.

18. (canceled)

19. (canceled)

20. The method of claim 16, wherein the absorber layer has a copper gallium indium ratio,, calculated as copper mole/(gallium mole+indium mole), in a range about 0.85 to about 0.95.

21. The method of claim 16, wherein the third layer comprises copper.

22. The method of claim 16, wherein the third layer comprises gallium and indium.

23. A method of forming a precursor layer stack on a substrate of a solar cell for forming an absorber layer, comprising:
providing a solar cell forming apparatus comprising a housing defining a vacuum chamber, a rotatable substrate apparatus within the housing for holding the substrate, and a plurality of sources disposed within the vacuum chamber between the rotatable substrate apparatus and housing, wherein the plurality of sources include a copper source, an indium source, a gallium source, and a selenium source;
rotating a solar cell substrate on the rotatable substrate apparatus while depositing from the plurality of sources a first layer comprising selenium and copper over at least a portion of a surface of a bottom electrode of the solar cell substrate, the first layer having a first concentration of copper; and
rotating a solar cell substrate on the rotatable substrate apparatus while depositing from the plurality of sources a second layer comprising selenium and at least two of the group consisting of copper, gallium or indium over at least the portion of the surface, the second layer having a second concentration of copper less than the first concentration of copper.

24. The method of claim 23, wherein said depositing steps are performed by, in order:
turning on the copper and selenium sources to deposit the first layer; and
turning off the copper source, turning on the indium and gallium sources, and keeping the selenium source on to deposit the second layer.

25. The method of claim 23, further comprising depositing a third layer comprising selenium, gallium and indium over at least the portion of the surface before depositing the first and second layers , wherein said depositing steps are performed by, in order:
turning on the indium, gallium and selenium sources to deposit the third layer;
turning off the indium and gallium sources, turning on the copper source, and keeping the selenium source on to deposit the first layer; and
turning off the copper source and turning on the indium and gallium sources to deposit the second layer.

26. The method of claim 23, wherein the copper and indium sources comprise sputtering sources and the selenium and gallium sources comprise evaporation sources.

27. The method of claim 26, wherein the plurality of sources further comprise a copper-gallium sputtering source.
